(19) United States
(12) Patent Application Publication
(10) Pub. No.: US 2025/0365908 A1
(43) Pub. Date: Nov. 27, 2025

(54) ELECTRONIC CONTROL DEVICE AND METHOD FOR MANUFACTURING ELECTRONIC CONTROL DEVICE

(71) Applicant: Hitachi Astemo, Ltd., Hitachinaka-shi, Ibaraki (JP)

(72) Inventors: Yusuke TAKAHASHI, Hitachinaka-shi, Ibaraki (JP); Takayuki FUKUZAWA, Hitachinaka-shi, Ibaraki (JP); Yoshio KAWAI, Hitachinaka-shi, Ibaraki (JP)

(73) Assignee: Hitachi Astemo, Ltd., Hitachinaka-shi, Ibaraki (JP)

(21) Appl. No.: 18/874,933

(22) PCT Filed: Jul. 8, 2022
(86) PCT No.: PCT/JP2022/027108

§ 371 Date: Dec. 13, 2024

(51) Int. Cl. H05K 9/00; H05K 5/00; H05K 5/04

(52) U.S. Cl. CPC H05K 9/0049; H05K 5/006; H05K 5/04

(57) ABSTRACT

An electronic control device includes a circuit board on which an electronic component is mounted, a conductive housing that houses the circuit board, and an electromagnetic wave shielding layer interposed between the circuit board and the housing. The housing has board pedestals for fixing the circuit board, and the electromagnetic wave shielding layer has compression regions pressed by the circuit board at positions away from the board pedestals by a predetermined distance.

### TECHNICAL FIELD

The present invention relates to an electronic control device and a method for manufacturing an electronic control device.

### BACKGROUND ART

In recent years, there is an increasing demand for advanced driving assistance systems (ADAS) and automatic driving (hereinafter, AD) systems. A semiconductor component such as a central processing unit (CPU) mounted on an electronic control device for ADAS or AD has a high operation frequency, and generation of electromagnetic wave noise is a problem. As an example of a shield structure for reducing electromagnetic wave noise radiated to an external environment, a structure for electrically connecting a circuit board and a metal housing for protecting the circuit board is known. In addition, PTL 1 discloses a shield structure using an electromagnetic wave shield sheet including a conductive layer containing a binder resin and a conductive filler and a cushion layer.

### CITATION LIST

### Patent Literature

PTL 1: JP 2020-057711 A

### SUMMARY OF INVENTION

### Technical Problem

In an in-vehicle electronic control device including an electronic control device including the electronic control devices for ADAS and AD, a processing speed tends to increase due to advancement of automatic driving or the like. Thus, the in-vehicle electronic control device is strongly required to improve shielding performance against electromagnetic wave noise.

An object of the present invention is to provide an electronic control device capable of improving shielding performance against electromagnetic wave noise.

### Solution to Problem

In order to solve the above problems, for example, configurations described in the claims are adopted.

The present application includes a plurality of means for solving the above-described problems, and one means of the plurality of means is an electronic control device including a circuit board on which an electronic component is mounted, a conductive housing that houses the circuit board, and an electromagnetic wave shielding layer interposed between the circuit board and the housing. The housing has board pedestals for fixing the circuit board, and the electromagnetic wave shielding layer has compression regions pressed by the circuit board at positions away from the board pedestals by a predetermined distance.

### Advantageous Effects of Invention

According to the present invention, the shielding performance against the electromagnetic wave noise can be improved.

Problems, configurations, and effects other than those described above will be clarified by the following description of embodiments.

### BRIEF DESCRIPTION OF DRAWINGS

FIG. 1 is a perspective view of an electronic control device according to a first embodiment.

FIG. 2 is a plan view of the electronic control device according to the first embodiment.

FIG. 3 is an exploded perspective view of the electronic control device according to the first embodiment.

FIG. 4 is a schematic plan view of a circuit board according to the first embodiment.

FIG. 5 is a sectional view taken along line V-V of the electronic control device illustrated in FIG. 2.

FIG. 6 is an enlarged view of a VI portion of the electronic control device illustrated in FIG. 5.

FIG. 7 is a flowchart for describing a method for manufacturing the electronic control device according to the first embodiment.

FIG. 8 is an enlarged sectional view of a main part of the electronic control device according to the first embodiment.

FIG. 9 is a sectional view of an electronic control device according to a second embodiment.

FIG. 10 is an enlarged sectional view of a main part of the electronic control device according to the second embodiment.

FIG. 11 is a sectional view of an electronic control device according to a third embodiment.

FIG. 12 is an enlarged sectional view of a main part of the electronic control device according to the third embodiment.

FIG. 13 is a sectional view of an electronic control device according to a fourth embodiment.

FIG. 14 is an enlarged sectional view of a main part of the electronic control device according to the fourth embodiment.

FIG. 15 is a sectional view of an electronic control device according to a fifth embodiment.

FIG. 16 is an enlarged sectional view of a main part of the electronic control device according to the fifth embodiment.

FIG. 17 is a sectional view of an electronic control device according to a sixth embodiment.

FIG. 18 is a sectional view of an electronic control device according to a seventh embodiment.

FIG. 19 is a sectional view of an electronic control device according to an eighth embodiment.

FIG. 20 is a plan view illustrating a main part of an electronic control device according to a ninth embodiment.

FIG. 21 is a plan view illustrating a main part of an electronic control device according to a tenth embodiment.

### DESCRIPTION OF EMBODIMENTS

Hereinafter, embodiments of the present invention will be described in detail with reference to the drawings. In the present specification and the drawings, elements having substantially the same function or configuration are denoted by the same reference sign, and redundant description is omitted.

### First Embodiment

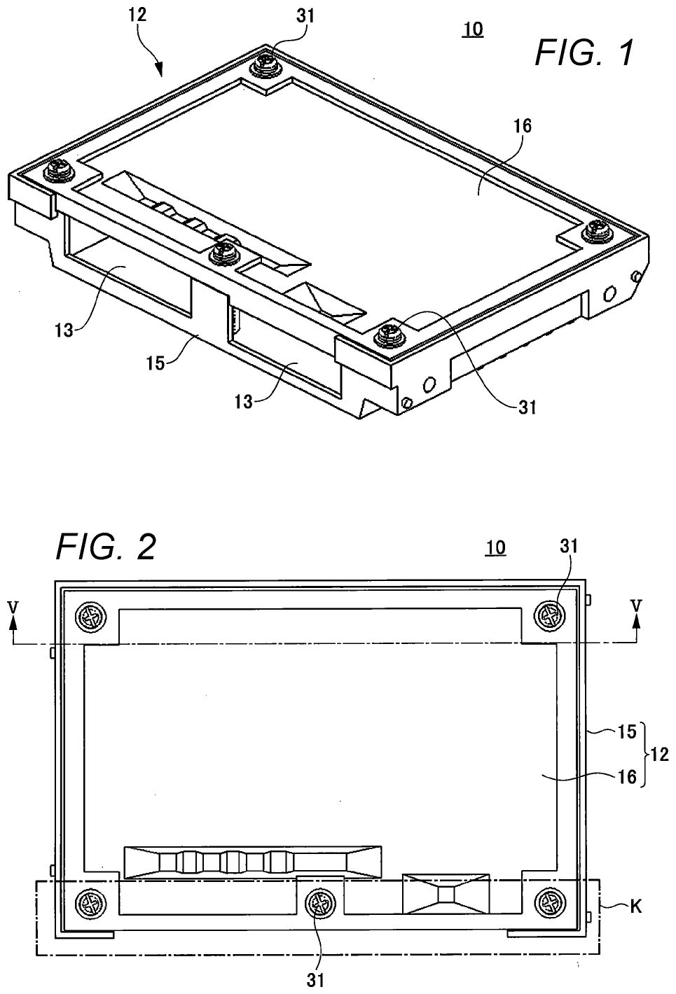

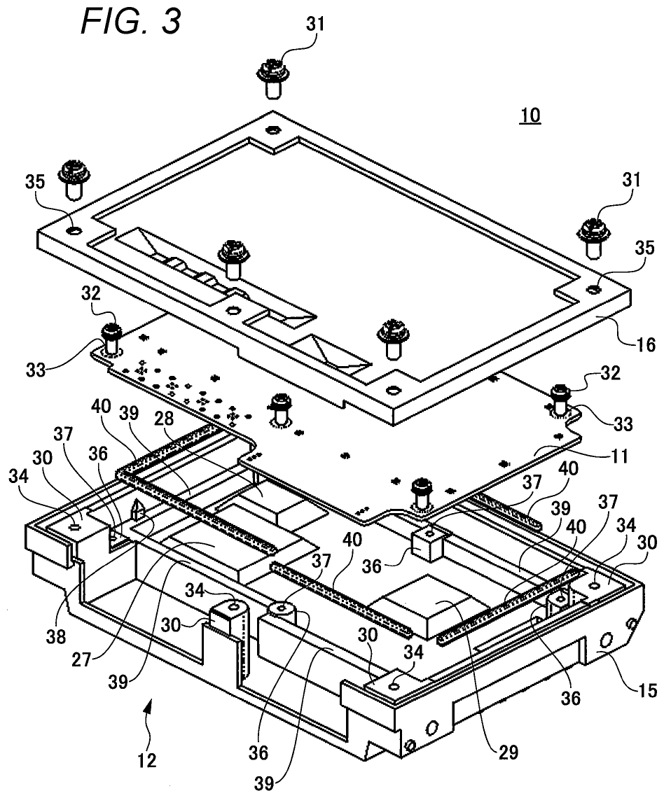

FIG. 1 is a perspective view of an electronic control device according to a first embodiment. FIG. 2 is a plan view of the electronic control device according to the first embodiment. FIG. 3 is an exploded perspective view of the electronic control device according to the first embodiment. In FIGS. 1 and 3, a connector to be described later is omitted.

As illustrated in FIGS. 1 to 3, an electronic control device 10 includes a circuit board 11 (FIG. 3) on which electronic components to be described later are mounted, and a conductive housing 12 that houses the circuit board 11. The electronic control device 10 is mounted on, for example, a vehicle such as an automobile for ADAS or AD.

The housing 12 is formed in a so-called flat a substantially rectangular parallelepiped shape with reduced height dimension (thickness dimension). The housing 12 has an opening 13 for connector connection. The housing 12 includes a metal housing base 15 and a metal housing cover 16. The housing base 15 and the housing cover 16 are fixed to each other by a plurality of screws 31.

More specifically, as illustrated in FIG. 3, a plurality of cover pedestals 30 are formed on the housing base 15. The cover pedestal 30 is formed integrally with the housing base 15. Screw holes 34 are provided in the cover pedestals 30. On the other hand, a plurality of cover fixing holes 35 are formed in the housing cover 16. The cover fixing holes 35 are through-holes for fixing the housing cover 16 to the housing base 15. The plurality of screws 31 described above are engaged with the screw holes 34 of the cover pedestals 30 through the corresponding cover fixing holes 35. The housing cover 16 is fixed to the housing base 15 by tightening the screws 31. The housing cover 16 is fixed to the housing base 15 with the screws 31 in this manner, and thus, the housing base 15 and the housing cover 16 are electrically and mechanically connected.

The housing base 15 and the housing cover 16 may be made of the same metal material, or may be made of different metal materials. In a case where the housing base 15 and the housing cover 16 are made of different metal materials, the housing base 15 is made of, for example, aluminum, and the housing cover 16 is made of, for example, iron on which rust prevention treatment is performed.

In the present specification, for the sake of convenience in description, a side on which the housing base 15 is disposed is referred to as a lower side, and a side on which the housing cover 16 is disposed is referred to as an upper side. In a case where the electronic control device 10 is mounted on the vehicle, it does not matter in what orientation the electronic control device 10 is mounted. In general, it is preferable to mount the electronic control device 10 on the vehicle such that the housing base 15 faces upward and the housing cover 16 faces downward.

The circuit board 11 is surrounded from above and below by the housing base 15 and the housing cover 16. The circuit board 11 is, for example, a printed wiring board using glass epoxy as a base material. The circuit board 11 is formed in a substantially rectangular shape.

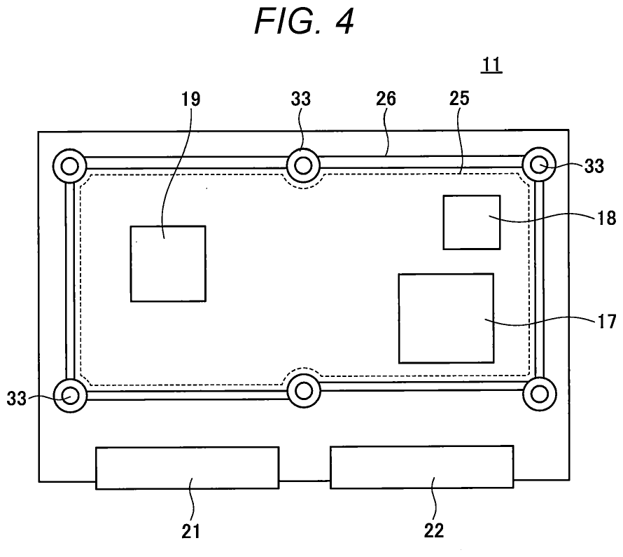

FIG. 4 is a schematic plan view of the circuit board according to the first embodiment.

As illustrated in FIG. 4, three electronic components 17, 18, and 19 and two connectors 21 and 22 are mounted on the circuit board 11. The circuit board 11 includes a circuit area 25 and a ground pattern 26. The electronic components 17, 18, and 19 are mounted in the circuit area 25 of the circuit board 11. The connectors 21 and 22 are mounted on an end portion of the circuit board 11.

The electronic components 17, 18, and 19 are, for example, LSI elements. LSI is an abbreviation of Large Scale Integration. Each of the LSI elements 17, 18, and 19 is a heat source and also a noise source. Electronic components other than the LSI elements are also mounted in the circuit area 25 of the circuit board 11, but electronic components, circuit wiring, and the like other than the LSI elements are omitted in FIG. 4. The connectors 21 and 22 are mounted on the end portion of the circuit board 11. A cable-side connector (not illustrated) can be connected to the connectors 21 and 22 through the opening 13 (FIG. 1) of the housing 12.

The ground pattern 26 is formed around the circuit area 25. The ground pattern 26 is a pattern made of, for example, a copper foil. The ground pattern 26 is formed in an annular shape so as to surround four sides of the circuit area 25. The ground pattern 26 may be formed so as to surround three sides of the circuit area 25.

As illustrated in FIG. 3, the circuit board 11 is fixed to the housing base 15 by the plurality of screws 32. The screws 32 are provided as an example of a fixture. Hereinafter, an attachment structure of the circuit board 11 using the screws 32 will be described in detail.

First, a plurality of board pedestals 36 are formed on the housing base 15. The board pedestals 36 are formed integrally with the housing base 15. Screw holes 37 are provided in an upper surface of the board pedestals 36. On the other hand, a plurality of board fixing holes 33 are provided in the circuit board 11. The plurality of board fixing holes 33 are through-holes for fixing the circuit board 11 to the housing base 15. Each board fixing hole 33 is formed on the ground pattern 26. In a portion where the board fixing hole 33 is formed, a part of the ground pattern 26 is formed in a circular shape slightly larger than an inner diameter of the board fixing hole 33, and the board fixing hole 33 is formed in this circular region.

The plurality of screws 32 described above are engaged with the screw holes 37 of the board pedestals 36 through the corresponding board fixing holes 33. The circuit board 11 is fixed to the housing base 15 by tightening the screws 32. In addition, protrusions 38 (FIG. 3) for positioning the board are formed at the housing base 15. A plurality of protrusions 38 are formed at appropriate positions of the housing base 15. The circuit board 11 is screwed to the housing base 15 in a state of being positioned by the plurality of protrusions 38.

Boss portions 27, 28, and 29 for heat dissipation are integrally formed on the housing base 15. The boss portion 27 is connected to the electronic component 17 via heat dissipating grease. In addition, the boss portion 28 is connected to the electronic component 18 via heat dissipating grease, and the boss portion 29 is connected to the electronic component 19 via heat dissipating grease. As a result, heat generated by each of the electronic components 17, 18, and 19 is transferred to the housing base 15 via the heat dissipating grease and is released from an outer surface of the housing base 15.

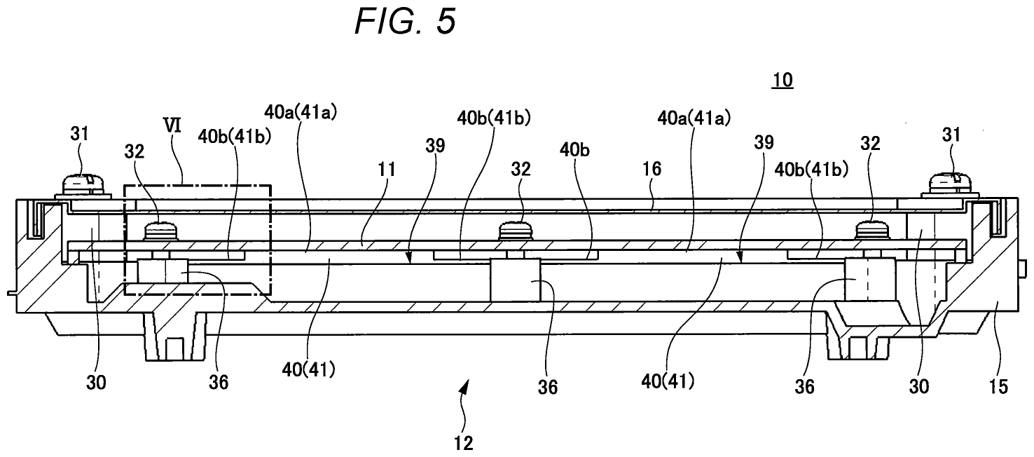

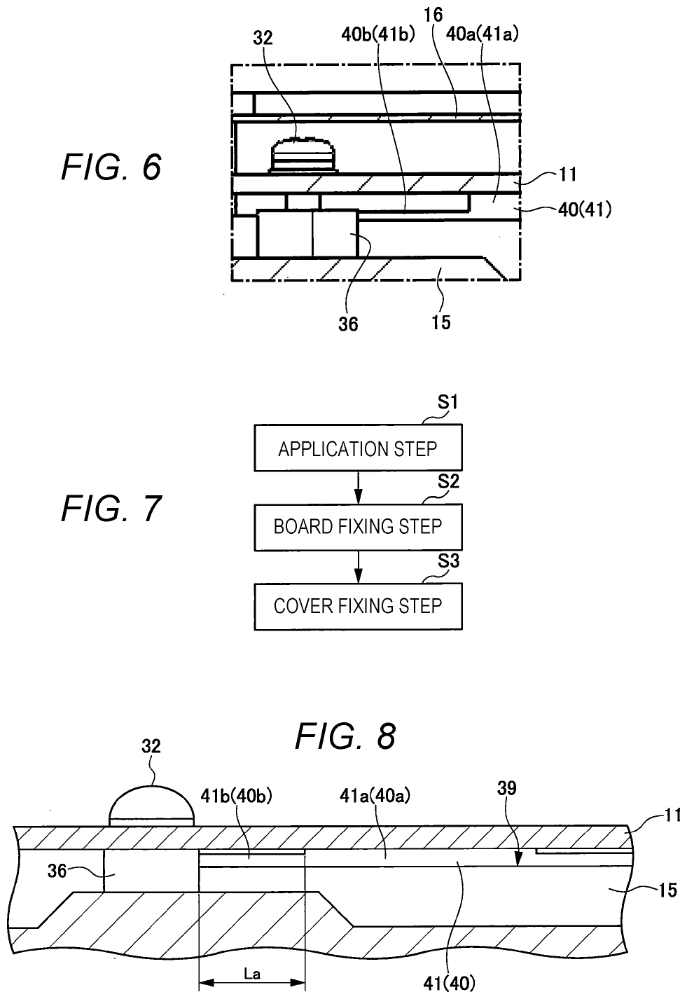

FIG. 5 is a sectional view taken along line V-V of the electronic control device illustrated in FIG. 2. FIG. 6 is an enlarged view of a VI portion of the electronic control device illustrated in FIG. 5. Note that, FIGS. 5 and 6 illustrate a state before the screws 32 are tightened.

As illustrated in FIGS. 5 and 6, an electromagnetic wave shielding layer 41 is interposed between the circuit board 11 and the housing base 15. As illustrated in FIG. 3, the electromagnetic wave shielding layer 41 is formed by supplying an electromagnetic wave shielding material 40 to an installation base 39 formed in the housing base 15. The electromagnetic wave shielding material 40 is a conductive shielding material. The installation base 39 is formed on the housing base 15 in order to install the electromagnetic wave shielding layer 41. The installation base 39 is formed along a shape of the ground pattern 26 of the circuit board 11 illustrated in FIG. 4. Thus, the electromagnetic wave shielding layer 41 is formed on the installation base 39 by the electromagnetic wave shielding material 40, and the electromagnetic wave shielding layer 41 is interposed between the circuit board 11 and the housing base 15. As a result, the ground pattern 26 of the circuit board 11 and the housing base 15 can be electrically connected.

The electromagnetic wave shielding material 40 is, for example, a liquid or paste adhesive installed as a cured in-place gasket (CIPG). The electromagnetic wave shielding material 40 is a shielding material containing a conductive filler. For example, a metal filler, more preferably a plated metal filler can be used as the conductive filler. A base material of the electromagnetic wave shielding material 40 is, for example, silicone, urethane, or the like.

Here, a method for manufacturing the electronic control device according to the first embodiment will be described with reference to FIG. 7.

As illustrated in FIG. 7, the method for manufacturing the electronic control device includes application step S1 of applying the electromagnetic wave shielding material 40 to the installation base 39 of the housing base 15, board fixing step S2 of fixing the circuit board 11 to the board pedestals 36 of the housing base 15, and cover fixing step S3 of fixing the housing cover 16 to the cover pedestal 30 of the housing base 15.

### Application Step

In application step S1, the electromagnetic wave shielding material 40 is applied to the installation base 39 of the housing base 15 by, for example, an application nozzle (not illustrated). At that time, as illustrated in FIGS. 5 and 6, the electromagnetic wave shielding material 40 is applied such that parts 40a of the electromagnetic wave shielding material 40 are higher than the board pedestals 36. A height of the installation base 39 and a height of the electromagnetic wave shielding material 40 are defined with an upper surface of the installation base 39 as a reference (0). The electromagnetic wave shielding material 40 is applied so as to be lower than the board pedestals 36 in the vicinity of the board pedestal 36. In addition, the electromagnetic wave shielding material 40 is applied so as to be higher than the board pedestals 36 except in the vicinity of the board pedestal 36 (in other words, a position away from the board pedestal 36). In addition, the electromagnetic wave shielding material 40 is thinly applied in the vicinity of the board pedestals 36, and is thickly applied at a position away from the board pedestals 36. Thus, the electromagnetic wave shielding material 40 after application has portions (hereinafter, also referred to as “first portions”) 40a having a large application thickness and higher than the board pedestals 36 and portions (hereinafter, also referred to as “second portions”) 40b having a small application thickness and lower than the board pedestals 36. As the adjustment of the application thickness of the electromagnetic wave shielding material 40, for example, a method for changing an application pressure (application amount per unit time) by the application nozzle, a method for changing the number of times of application by the application nozzle, and the like can be considered.

After the electromagnetic wave shielding material 40 is applied to the installation base 39 of the housing base 15 in this manner, the electromagnetic wave shielding material 40 is cured to a predetermined hardness before board fixing step S2 to be described later is performed. The predetermined hardness is such hardness that in a case where the first portions 40a of the electromagnetic wave shielding material 40 are pressed by the circuit board 11 in board fixing step S2 to be described later, the first portions 40a can be compressed and deformed by receiving a pressing force of the circuit board 11. The electromagnetic wave shielding layer 41 is a shielding layer formed by the electromagnetic wave shielding material 40 applied to the installation base 39.

### Board Fixing Step

In board fixing step S2, the circuit board 11 is attached to the board pedestals 36 of the housing base 15 by using the screws 32. At that time, the circuit board 11 is fixed by the screws 32 such that the first portions 40a of the electromagnetic wave shielding material 40 are pressed by the circuit board 11. Details will be described below.

First, the first portions 40a of the electromagnetic wave shielding material 40 are higher than the board pedestals 36. Thus, the ground pattern 26 of the circuit board 11 comes into contact with the first portions 40a of the electromagnetic wave shielding material 40. In addition, in a state where the screws 32 are screwed into the screw holes 37 of the board pedestal 36 through the board fixing holes 33 of the circuit board 11 and the circuit board 11 is fixed to the housing base 15 by tightening the screws 32 in this state, as illustrated in FIG. 8, the first portions 40a of the electromagnetic wave shielding material 40 are pressed by the circuit board 11, and these pressed portions become compression regions 41a. In addition, the ground pattern 26 of the circuit board 11 is electrically connected to the housing base 15 by the electromagnetic wave shielding layer 41.

On the other hand, the second portions 40b of the electromagnetic wave shielding material 40 are lower than the board pedestals 36. Thus, the second portions 40b of the electromagnetic wave shielding material 40 are not pressed by the circuit board 11 even in a state where the circuit board 11 is fixed to the housing base 15 by tightening the screws 32, and these portions that are not pressed become non-compression regions 41b. The non-compression regions 41b are formed in the vicinity of the board pedestals 36 than the compression regions 41a, and the compression regions 41a are formed at positions farther from the board pedestals 36 than the non-compression regions 41b. The compression regions 41a are formed at positions away from the board pedestal 36 by a predetermined distance La (FIG. 8) due to the presence of the non-compression regions 41b. The predetermined distance La is equal to or less than a half wavelength of a noise frequency to be shielded. However, when the predetermined distance La is too short, a deformation amount of the circuit board 11 becomes large in the vicinity of the board pedestals 36 when the screws 32 are tightened. Thus, the predetermined distance La is preferably set such that the deformation amount of the circuit board 11 in the vicinity of the board pedestals 36 does not become excessive when the screws 32 are tightened.

### Cover Fixing Step

In cover fixing step S3, the housing cover 16 is attached to the cover pedestals 30 of the housing base 15 by using the screws 31. As a result, the circuit board 11 is housed in the housing 12.

In the electronic control device 10 and the manufacturing method thereof according to the first embodiment described above, the first portions 40a of the electromagnetic wave shielding material 40 applied to the installation base 39 of the housing base 15 higher than the board pedestals 36 form the compression regions 41a pressed by the circuit board 11. In the compression regions 41a, a density of the conductive filler contained in the electromagnetic wave shielding material 40 is higher than that in the non-compression regions 41b. Thus, an impedance of the electromagnetic wave shielding layer 41 is lowered as compared with a case where the electromagnetic wave shielding layer 41 does not have the compression regions 41a. Therefore, electromagnetic wave noise shielding performance by the electromagnetic wave shielding layer 41 can be enhanced.

In addition, in the first embodiment, the circuit board 11 presses the electromagnetic wave shielding layer 41 at a position away from the board pedestals 36 by the predetermined distance La. Thus, the deformation of the circuit board 11 due to the tightening of the screws 32 can be suppressed.

In addition, in the first embodiment, the distance La from the board pedestal s36 to the compression regions 41a is equal to or less than the half wavelength of the noise frequency to be shielded. Thus, even in a case where the non-compression regions 41b are interposed between the board pedestals 36 and the compression regions 41a, the electromagnetic wave noise to be shielded can be effectively blocked by the electromagnetic wave shielding layer 41.

In addition, in the first embodiment, the ground pattern 26 of the circuit board 11 and the housing base 15 are electrically connected by the electromagnetic wave shielding layer 41. As a result, a potential of the ground pattern 26 is maintained at the same level as a potential of the housing 12. Thus, the potential of the ground pattern 26 in the circuit board 11 can be stabilized.

In addition, in the first embodiment, an application height when the electromagnetic wave shielding material 40 is applied to the installation base 39 of the housing base 15 is adjusted, and thus, the second portions 40b of the electromagnetic wave shielding material 40 are the non-compression regions 41b that are not pressed by the circuit board 11. The non-compression regions 41b are formed in the vicinity of the board pedestals 36. As a result, in the vicinity of the board pedestals 36, stress generated in the electromagnetic wave shielding layer 41 by the fastening of the screws 32 can be reduced. In addition, in the vicinity of the board pedestals 36, it is possible to reduce the deformation of the circuit board 11 due to the tightening of the screws 32 and distortion of solder portions of the electronic components due to the deformation of the circuit board 11.

In addition, in the first embodiment, the electromagnetic wave shielding material 40 is applied to the installation base 39 of the housing base 15 to form the electromagnetic wave shielding layer 41. As a result, cost required for forming the electromagnetic wave shielding layer can be reduced as compared with a case where the electromagnetic wave shielding layer is formed by pasting components such as an electromagnetic wave shield sheet and an EMI gasket.

Note that, in the first embodiment, the electromagnetic wave shielding material 40 is applied such that the second portions 40b are lower than the board pedestals 36 in the vicinity of the board pedestals 36, but the present invention is not limited thereto. The electromagnetic wave shielding material 40 may be applied such that the second portions 40b have the same height as the board pedestals 36 in the vicinity of the board pedestals 36.

### Second Embodiment

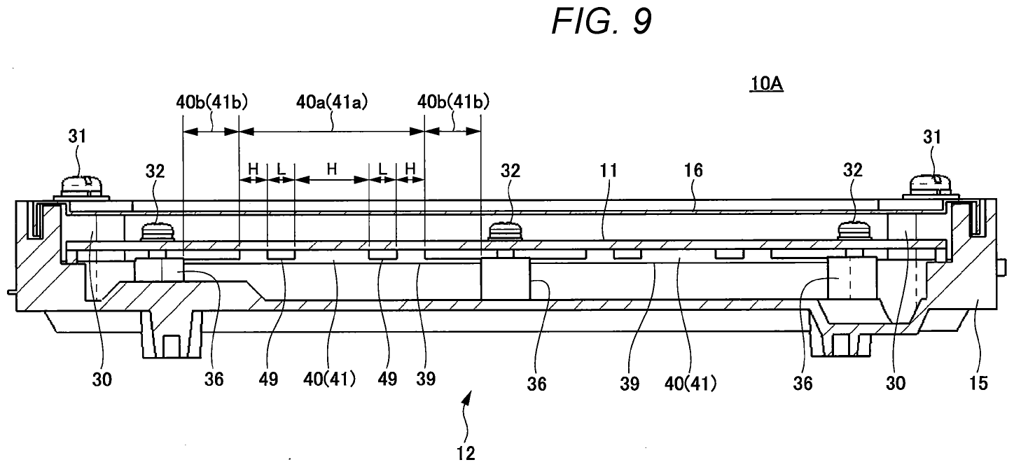

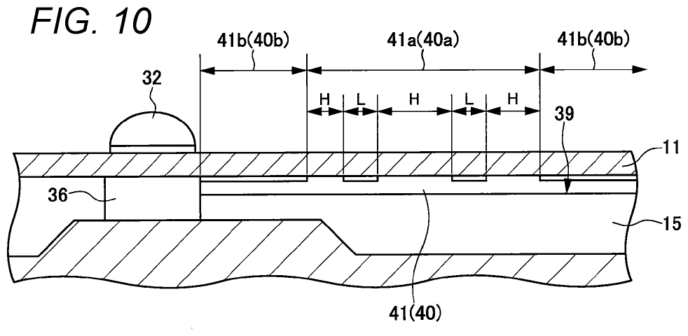

FIG. 9 is a sectional view of an electronic control device according to a second embodiment. FIG. 10 is an enlarged sectional view of a main part of the electronic control device according to the second embodiment.

As illustrated in FIGS. 9 and 10, an electronic control device 10A according to the second embodiment is different from the case of the first embodiment (FIG. 5) in that the compression regions 41a of the electromagnetic wave shielding layer 41 include high compression regions H and low compression regions L.

The high compression region H is a region pressed by the circuit board 11 with a higher compression rate than the low compression region L when the circuit board 11 is attached to the housing base 15 with the screws 32. The low compression region L is a region pressed by the circuit board 11 with a lower compression rate than the high compression region H, or a region not pressed by the circuit board 11 similarly to the non-compression regions 41b.

The high compression region H is a region where the electromagnetic wave shielding material 40 is applied higher than the board pedestal 36 in a case where the electromagnetic wave shielding material 40 is applied to the installation base 39 of the housing base 15 in application step S1 described above. On the other hand, the low compression region L is a region where the electromagnetic wave shielding material 40 is applied lower than the high compression region H. Thus, an application thickness of the electromagnetic wave shielding material 40 in the low compression region L is thinner than an application thickness of the electromagnetic wave shielding material 40 in the high compression region H. Accordingly, at a stage before the circuit board 11 is attached, a recess 49 (FIG. 9) is formed in a surface of the electromagnetic wave shielding material 40 (first portion 40a) applied higher than the board pedestal 36 due to a difference in the application thickness described above. Note that, the application thickness of the electromagnetic wave shielding material 40 in the low compression region L may be the same as or different from the application thickness of the electromagnetic wave shielding material 40 in the non-compression region 41b.

As described above, the configuration in which the compression region 41a of the electromagnetic wave shielding layer 41 includes the high compression region H and the low compression region L is adopted, and thus, an usage amount of the electromagnetic wave shielding material 40 necessary for forming the electromagnetic wave shielding layer 41 can be reduced. As a result, cost of the electronic control device 10A can be reduced.

### Third Embodiment

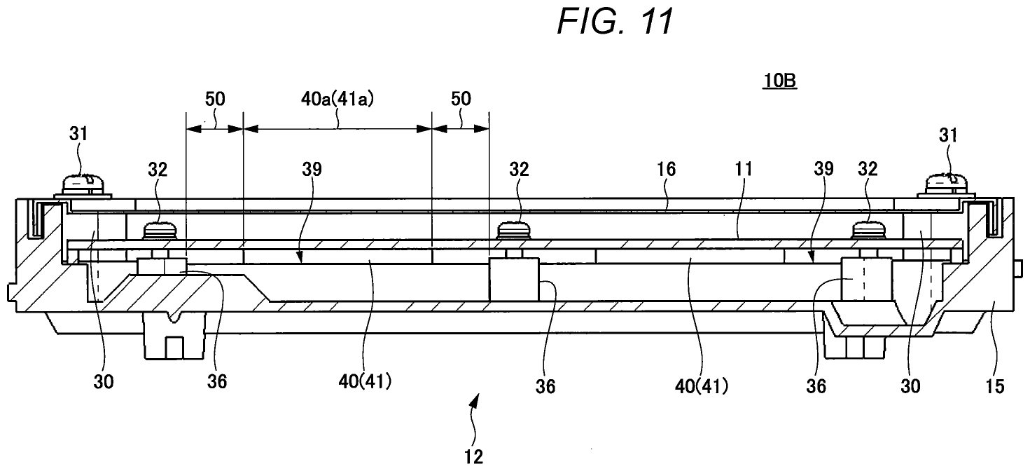

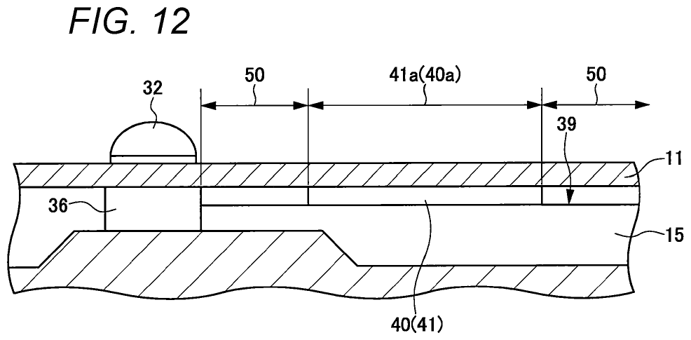

FIG. 11 is a sectional view of an electronic control device according to a third embodiment. FIG. 12 is an enlarged sectional view of a main part of the electronic control device according to the third embodiment.

As illustrated in FIGS. 11 and 12, an electronic control device 10B according to the third embodiment is different from the case of the first embodiment (FIG. 5) in that the electromagnetic wave shielding layer 41 is disposed at a position except in the vicinity of the board pedestal 36.

The electromagnetic wave shielding layer 41 does not have the non-compression region 41b (FIG. 5), and has only the compression region 41a. In order to form such an electromagnetic wave shielding layer 41, when the electromagnetic wave shielding material 40 is applied to the installation base 39 in application step S1 described above, the electromagnetic wave shielding material 40 may be applied to the position except in the vicinity of the board pedestal 36. That is, the electromagnetic wave shielding material 40 is not applied to the vicinity of the board pedestal 36, and the electromagnetic wave shielding material 40 is applied to a position away from the board pedestal 36. As a result, there is a region 50 where the electromagnetic wave shielding layer 41 is not formed in the vicinity of the board pedestal 36. In this region 50, the upper surface of the installation base 39 is not covered with the electromagnetic wave shielding material 40 (electromagnetic wave shielding layer 41).

As described above, in the third embodiment, an application region of the electromagnetic wave shielding material 40 is limited to the position away from the board pedestal 36, and thus, the electromagnetic wave shielding layer 41 is disposed at a position except in the vicinity of the board pedestal 36. As a result, the usage amount of the electromagnetic wave shielding material 40 necessary for forming the electromagnetic wave shielding layer 41 can be reduced, and cost of the electronic control device 10B can be reduced.

### Fourth Embodiment

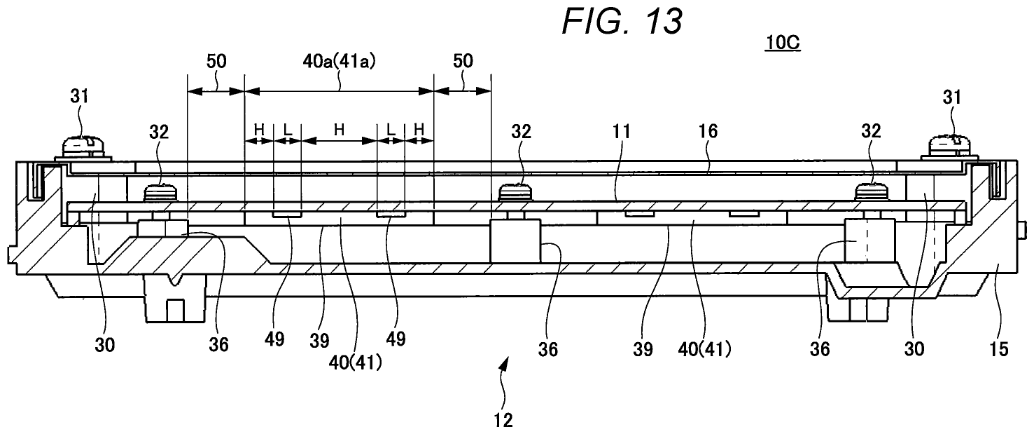

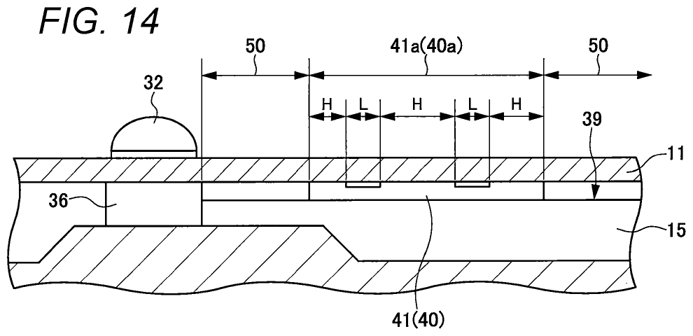

FIG. 13 is a sectional view of an electronic control device according to a fourth embodiment. FIG. 14 is an enlarged sectional view of a main part of the electronic control device according to the fourth embodiment.

As illustrated in FIGS. 13 and 14, an electronic control device 10C according to the fourth embodiment is different from the case of the third embodiment (FIGS. 11 and 12) in that a compression region 41a of an electromagnetic wave shielding layer 41 includes a high compression region H and a low compression region L. As a result, the amount of the electromagnetic wave shielding material 40 used can be further reduced as compared with the third embodiment.

### Fifth Embodiment

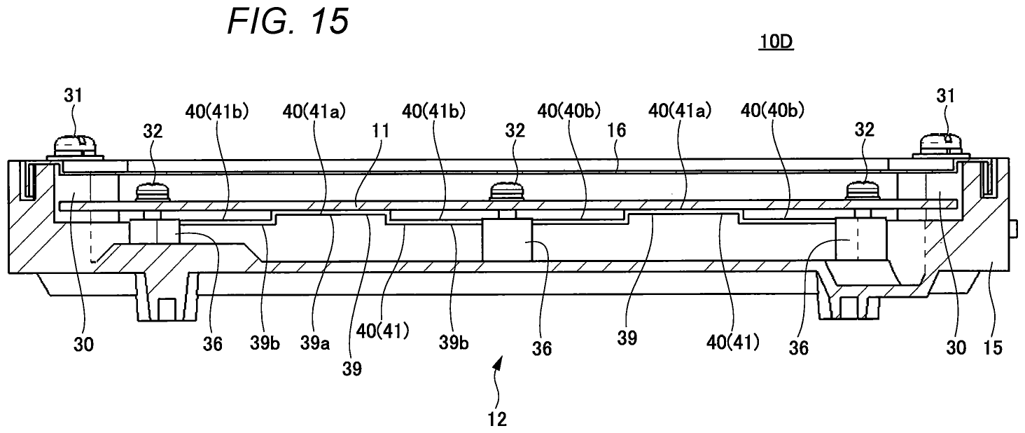

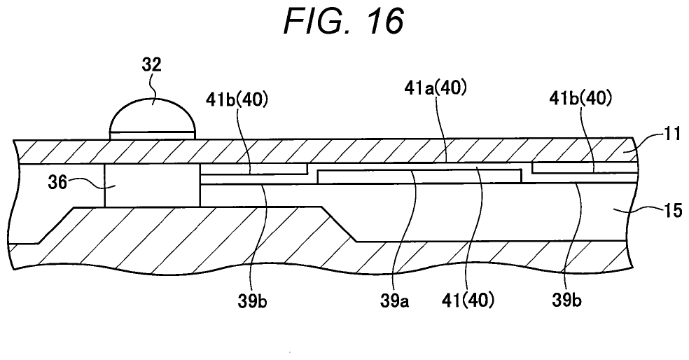

FIG. 15 is a sectional view of an electronic control device according to a fifth embodiment. FIG. 16 is an enlarged sectional view of a main part of an electronic control device according to a fifth embodiment.

As illustrated in FIGS. 15 and 16, the electronic control device 10D according to the fifth embodiment is different from the case of the first embodiment (FIGS. 5 to 8) in that a height difference is provided in the installation base 39 of the housing base 15. Specifically, the installation base 39 of the housing base 15 includes first installation pedestals 39a far from the board pedestals 36 and second installation pedestal 39b closer to the board pedestals 36 than the first installation pedestals 39a. In addition, a height of the first installation pedestal 39a is higher than a height of the second installation pedestal 39b.

On the other hand, the electromagnetic wave shielding layer 41 has a compression region 41a installed on the first installation pedestal 39a and a non-compression region 41b installed on the second installation pedestal 39b. The compression region 41a and the non-compression region 41b are formed by applying the electromagnetic wave shielding material 40 with a uniform thickness to each of the first installation pedestal 39a and the second installation pedestal 39b in application step S1 described above and fixing the circuit board 11 to the board pedestals 36 by using the screws 32 in subsequent board fixing step S2.

The height of the first installation pedestal 39a may be a height that allows the electromagnetic wave shielding material 40 applied to the first installation pedestal 39a to be pressed against the circuit board 11 to form the compression region 41a when the circuit board 11 is attached to the board pedestals 36 with the screws 32.

As described above, the height difference on the installation base 39 of the housing base 15 is provided, and thus, the usage amount of the electromagnetic wave shielding material 40 necessary for forming the electromagnetic wave shielding layer 41 can be reduced. In addition, in application step S1, the application thickness of the electromagnetic wave shielding material 40 can be made uniform.

### Sixth Embodiment

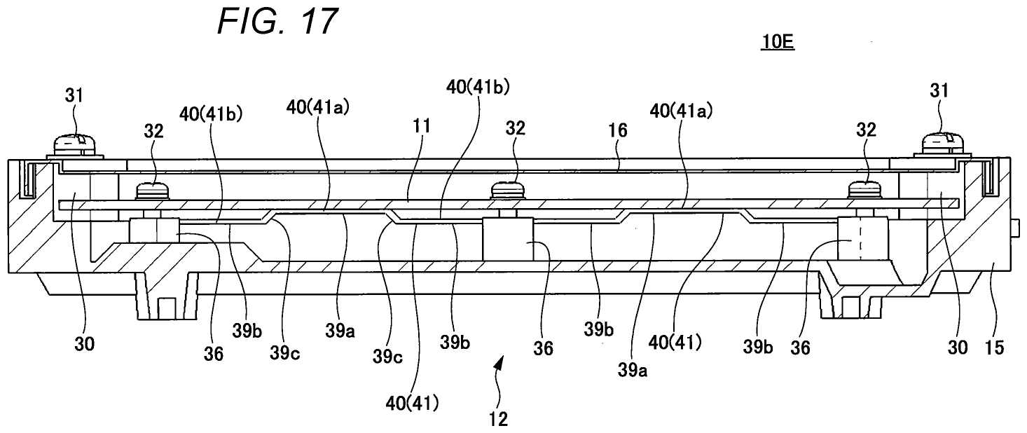

FIG. 17 is a sectional view of an electronic control device according to a sixth embodiment.

As illustrated in FIG. 17, an electronic control device 10E according to the sixth embodiment is different from the case of the fifth embodiment (FIG. 15) in that an inclined portion 39c is formed at a boundary between the first installation pedestal 39a and the second installation pedestal 39b. An inclination angle of the inclined portion 39c is an angle defined based on an upper surface of the second installation pedestal 39b, and is set in a range of, for example, 15 degrees or more and 75 degrees or less.

As described above, the inclined portion 39c is formed at the boundary between the first installation pedestal 39a and the second installation pedestal 39b, and thus, it is possible to further reduce the stress generated in the electromagnetic wave shielding layer 41 when the circuit board 11 is attached to the board pedestals 36 of the housing base 15 by using the screws 32 in board fixing step S2 described above.

### Seventh Embodiment

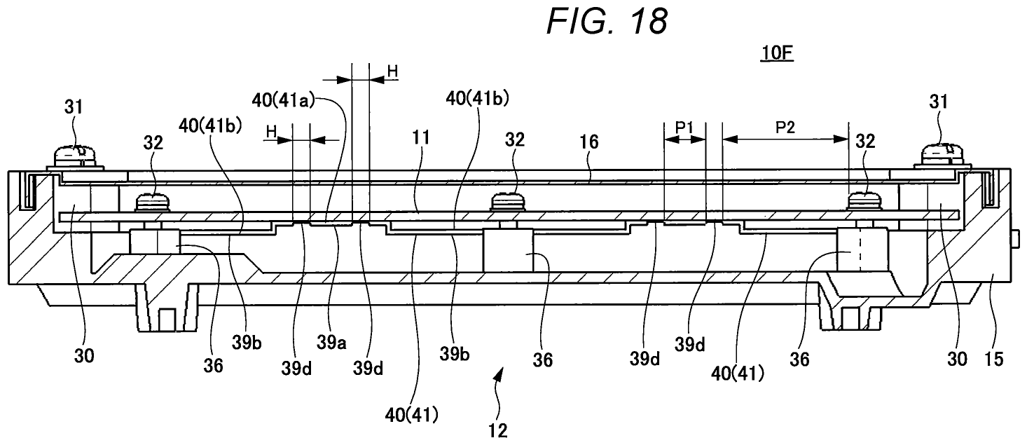

FIG. 18 is a sectional view of an electronic control device according to a seventh embodiment.

As illustrated in FIG. 18, an electronic control device 10F according to the seventh embodiment is different from the case of the fifth embodiment (FIG. 15) in that a plurality of projections 39d are provided on an installation surface (upper surface) of the first installation pedestal 39a on which the electromagnetic wave shielding layer 41 is installed. In the present embodiment, as an example, two projections 39d are formed on the installation surface of the first installation pedestal 39a. Each projection 39d is formed in a convex shape on the installation surface of the first installation pedestal 39a. In addition, an interval P1 between the projections 39d adjacent to each other on the installation surface of the first installation pedestal 39a is set to be equal to or less than the half wavelength of the noise frequency to be shielded. In addition, an interval P2 between the screw 32 for fixing the circuit board 11 and the projection 39d closest to the screw 32 is also set to be equal to or less than the half wavelength of the noise frequency to be shielded.

In a case where the plurality of projections 39d are formed on the installation surfaces of the first installation pedestals 39a, the high compression region H is formed by the presence of the projection 39d in the range of the compression region 41a by applying the electromagnetic wave shielding material 40 to the first installation pedestal 39a and the second installation pedestal 39b with a uniform thickness in application step S1 described above and in subsequent board fixing step S2 and fixing the circuit board 11 to the board pedestals 36 with the screws 32. The high compression region H is a compression region formed when the electromagnetic wave shielding material 40 applied so as to cover the projections 39d is pressed against the circuit board 11.

In the seventh embodiment, the configuration in which the plurality of projections 39d are provided on the installation surface of the first installation pedestal 39a and the high compression region H is formed within the range of the compression region 41a due to the presence of each projection 39d is adopted, and thus, it is possible to further improve the electromagnetic wave noise shielding performance by the electromagnetic wave shielding layer 41. In addition, in the seventh embodiment, since the interval P1 between the adjacent projections 39d and the interval P2 between the screw 32 and the projection 39d are set to be equal to or less than the half wavelength of the noise frequency to be shielded, and thus, the shielding performance against electromagnetic wave noise to be shielded can be further enhanced.

### Eighth Embodiment

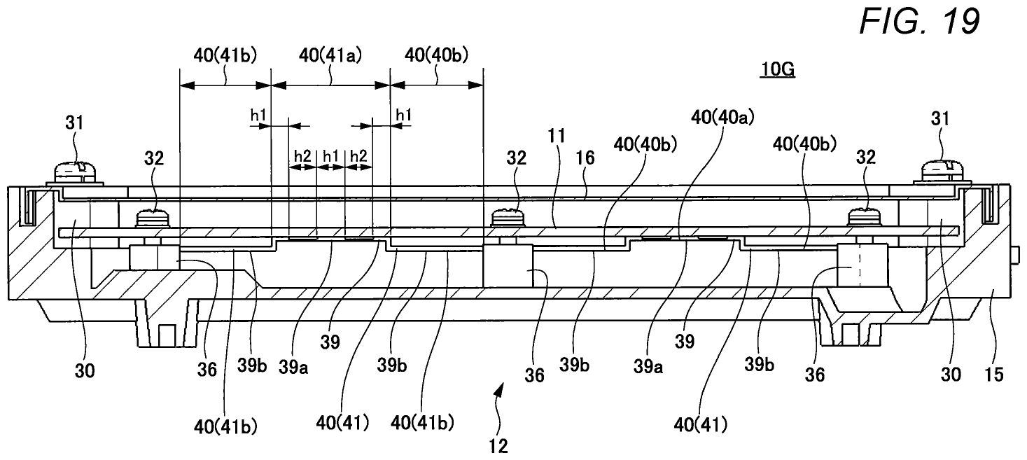

FIG. 19 is a sectional view of an electronic control device according to an eighth embodiment.

As illustrated in FIG. 19, an electronic control device 10G according to the eighth embodiment is different from the case of the fifth embodiment (FIG. 15) in that the compression region 41a of the electromagnetic wave shielding layer 41 installed on the first installation pedestal 39a includes a first compression region h1 and a second compression region h2 having compression rates different from each other. The first compression region h1 is a region having a compression rate higher than that of the second compression region h2.

The first compression region h1 and the second compression region h2 are formed by the following method.

First, in application step S1 described above, when the electromagnetic wave shielding material 40 is applied to the first installation pedestal 39a, the application thickness is increased at a position corresponding to the first compression region h1, and the application thickness is decreased at a position corresponding to the second compression region h2. As a result, a recess is formed on the surface (upper surface) of the electromagnetic wave shielding material 40 applied to the first installation pedestal 39a.

Thereafter, in board fixing step S2 described above, in a case where the circuit board 11 is attached to the board pedestals 36 with the screws 32, the electromagnetic wave shielding material 40 covering the first installation pedestals 39a is pressed by the circuit board 11. At this time, a portion where the application thickness of the electromagnetic wave shielding material 40 is thick becomes the first compression region h1, and a portion where the application thickness of the electromagnetic wave shielding material 40 is thin becomes the second compression region h2.

As described above, the first compression region h1 and the second compression region h2 are provided in the electromagnetic wave shielding layer 41 installed on the first installation pedestal 39a, and thus, the usage amount of the electromagnetic wave shielding material 40 required for forming the electromagnetic wave shielding layer 41 can be reduced.

### Ninth Embodiment

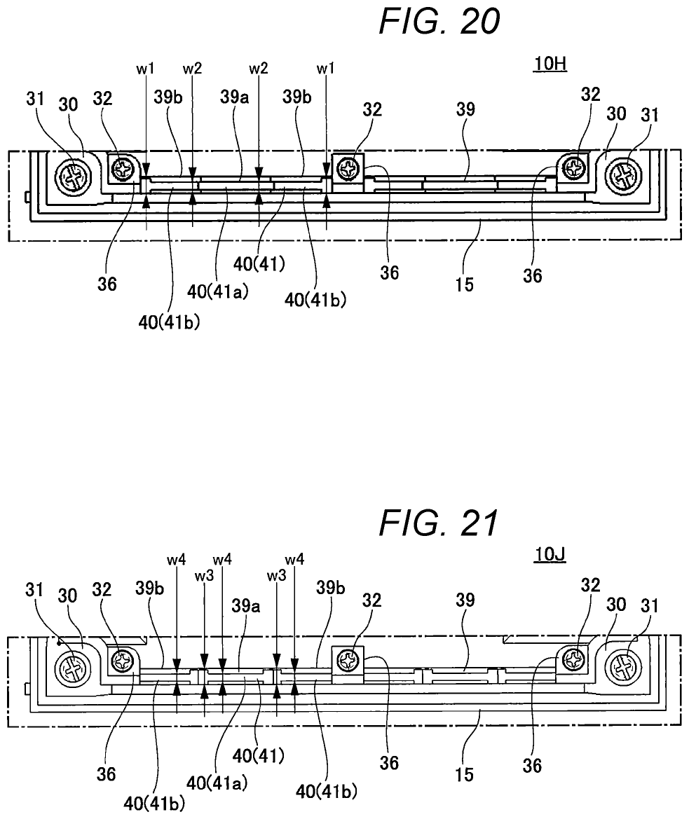

FIG. 20 is a plan view illustrating a main part of an electronic control device according to a ninth embodiment. Note that, FIG. 20 is a diagram obtained by cutting out a portion K in FIG. 2. However, in FIG. 20, the circuit board and the housing cover are not illustrated.

As illustrated in FIG. 20, an electronic control device 10H according to the ninth embodiment is characterized in that an installation width w1 of the electromagnetic wave shielding layer 41 in the vicinity (immediate vicinity) of the board pedestals 36 is wider than an installation width w2 of the electromagnetic wave shielding layer 41 in a portion except in the vicinity of the board pedestals 36 as compared with the case of the fifth embodiment (FIG. 15). More specifically, on the first installation pedestal 39a far from the board pedestals 36, the compression region 41a of the electromagnetic wave shielding layer 41 is formed with a uniform installation width w2. On the other hand, in the second installation pedestal 39b close to the board pedestals 36, the non-compression region 41b of the electromagnetic wave shielding layer 41 is formed with different installation widths w1 and w2. Specifically, in the second installation pedestal 39b, an installation width of the electromagnetic wave shielding layer 41 in the immediate vicinity of the board pedestal 36 is w1, and an installation width of the electromagnetic wave shielding layer 41 far from the board pedestal 36 is w2.

The electronic control device 10H according to the ninth embodiment is obtained by applying the electromagnetic wave shielding material 40 with a first application width corresponding to the installation width w1 in the vicinity (immediate vicinity) of the board pedestal 36 and applying the electromagnetic wave shielding material 40 with a second application width corresponding to the installation width w2 in a portion except in the vicinity of the board pedestal 36 in application step S1 described above.

As described above, the installation width w1 of the electromagnetic wave shielding layer 41 in the vicinity of the board pedestal 36 is set to be wider than the installation width w2 of the electromagnetic wave shielding layer 41 in the portion except in the vicinity of the board pedestal 36, and thus, it is possible to secure a wide contact area between the circuit board 11 and the electromagnetic wave shielding layer 41 in the vicinity of the board pedestal 36 when the circuit board 11 is attached to the board pedestals 36 of the housing base 15 by using the screws 32 in board fixing step S2 described above. Thus, the stress generated in the electromagnetic wave shielding layer 41 can be further reduced.

### Tenth Embodiment

FIG. 21 is a plan view illustrating a main part of an electronic control device according to a tenth embodiment. Note that, FIG. 21 is a diagram obtained by cutting out a portion K in FIG. 2. However, in FIG. 21, the circuit board and the housing cover are not illustrated.

As illustrated in FIG. 21, an electronic control device 10J according to the tenth embodiment is characterized in that an installation width w3 of the electromagnetic wave shielding layer 41 at a boundary portion between the first installation pedestal 39a and the second installation pedestal 39b is wider than an installation width w4 of the electromagnetic wave shielding layer 41 at a portion other than the boundary portion, as compared with the case of the fifth embodiment (FIG. 15). More specifically, the compression region 41a of the electromagnetic wave shielding layer 41 is formed on the first installation pedestal 39a far from the board pedestal 36 such that both ends are wide. On the other hand, in the second installation pedestal 39b close to the board pedestal 36, the non-compression region 41b of the electromagnetic wave shielding layer 41 is formed such that one end portion close to the first installation pedestal 39a becomes wide.

The electronic control device 10J according to the tenth embodiment is obtained by applying the electromagnetic wave shielding material 40 such that an application width of the electromagnetic wave shielding material 40 at the boundary portion between the first installation pedestal 39a and the second installation pedestal 39b is wider than an application width of the electromagnetic wave shielding material 40 at the portion other than the boundary portion in application step S1 described above.

As described above, the installation width w3 of the electromagnetic wave shielding layer 41 at the boundary portion between the first installation pedestal 39a and the second installation pedestal 39b is set to be wider than the installation width w4 of the electromagnetic wave shielding layer 41 at the portion other than the boundary portion, and thus, it is possible to ensure a wide contact area between the circuit board 11 and the electromagnetic wave shielding layer 41 at the boundary portion when the circuit board 11 is attached to the board pedestals 36 of the housing base 15 by using the screws 32 in board fixing step S2 described above. Thus, the stress generated in the electromagnetic wave shielding layer 41 can be further reduced.

### Modifications and the Like

Note that, the present invention is not limited to the above-described embodiments, and includes various modifications. For example, in the above-described embodiments, the contents of the present invention are described in detail for easy understanding, but the present invention is not necessarily limited to the embodiment including all the configurations described in the above-described embodiments. In addition, a part of the configuration of one embodiment can be replaced with the configuration of another embodiment. In addition, it is also possible to add the configuration of another embodiment to the configuration of a certain embodiment. In addition, a part of the configuration of each embodiment can be deleted, another configuration can be added, or another configuration can be substituted.

For example, in the above-described embodiments, the electromagnetic wave shielding layer 41 is interposed between the housing base 15 and the circuit board 11, but the present invention is not limited thereto. The electromagnetic wave shielding layer 41 may be interposed between the housing cover 16 and the circuit board 11.

In addition, the electronic component may be mounted on only one surface of the circuit board 11, or may be mounted on both surfaces of the circuit board 11.

### Reference Signs List

10, 10A, 10B, 10C, 10D, 10E, 10F, 10G, 10J . . . electronic control device
11 circuit board
12 housing
15 housing base
16 housing cover
17, 18, 19 electronic component
32 screw (fixture)
39 installation base
39a first installation pedestal
39b second installation pedestal
39c inclined portion
39d projection
40 electromagnetic wave shielding material
41 electromagnetic wave shielding layer
41a compression region
41b non-compression region
49 recess
H high compression region
h1 first compression region
h2 second compression region
L low compression region
w1, w2, w3, w4 installation width

1. An electronic control device comprising:
a circuit board on which an electronic component is mounted;
a conductive housing that houses the circuit board; and
an electromagnetic wave shielding layer interposed between the circuit board and the housing,
wherein the housing includes board pedestals for fixing the circuit board, and
the electromagnetic wave shielding layer has compression regions pressed by the circuit board at positions away from the board pedestals by a predetermined distance.

2. The electronic control device according to claim 1, wherein the predetermined distance is equal to or less than a half wavelength of a noise frequency to be shielded.

3. The electronic control device according to claim 1, wherein the electromagnetic wave shielding layer has non-compression regions in the vicinity of the board pedestals.

4. The electronic control device according to claim 1, wherein the compression regions of the electromagnetic wave shielding layer include high compression regions and low compression regions.

5. The electronic control device according to claim 1, wherein the electromagnetic wave shielding layer is disposed at a position except in the vicinity of the board pedestals.

6. The electronic control device according to claim 1, wherein
the housing includes installation pedestals on which the electromagnetic wave shielding layer is installed, and
the installation pedestals include first installation pedestals far from the board pedestals and second installation pedestals closer to the board pedestals than the first installation pedestals, and a height of the first installation pedestal is higher than a height of the second installation pedestal.

7. The electronic control device according to claim 6, wherein an inclined portion is formed at a boundary between the first installation pedestal and the second installation pedestal.

8. The electronic control device according to claim 6, wherein the housing includes a plurality of projections that form high compression regions within a range of the compression region, the projections being portions each formed in a convex shape on an installation surface of the first installation pedestal.

9. The electronic control device according to claim 8, wherein an interval between adjacent projections of the plurality of projections is equal to or less than a half wavelength of a noise frequency to be shielded.

10. The electronic control device according to claim 8, wherein
the circuit board is fixed to the board pedestals of the housing by a fixture, and
an interval between a projection closest to the fixture, among the plurality of projections, and the fixture is equal to or less than a half wavelength of a noise frequency to be shielded.

11. The electronic control device according to claim 6, wherein the electromagnetic wave shielding layer installed on the first installation pedestals includes first compression regions and second compression regions having a lower compression rate than the first compression regions.

12. The electronic control device according to claim 1, wherein an installation width of the electromagnetic wave shielding layer in the vicinity of the board pedestal is wider than an installation width of the electromagnetic wave shielding layer in a portion except in the vicinity of the board pedestal.

13. The electronic control device according to claim 6, wherein an installation width of the electromagnetic wave shielding layer at a boundary portion between the first installation pedestal and the second installation pedestal is wider than an installation width of the electromagnetic wave shielding layer at a portion other than the boundary portion.

14. A method for manufacturing an electronic control device that includes a circuit board on which an electronic component is mounted, a conductive housing for housing the circuit board, and an electromagnetic wave shielding layer interposed between the circuit board and the housing, the method comprising:
an application step of applying an electromagnetic wave shielding material to installation pedestals of the housing such that at least a part of the electromagnetic wave shielding material is higher than board pedestals formed in the housing for fixing the circuit board; and
a board fixing step of fixing the circuit board to the board pedestals of the housing such that at least a part of the electromagnetic wave shielding material applied to the installation pedestals of the housing is pressed by the circuit board.

15. The method for manufacturing an electronic control device according to claim 14, wherein, in the application step, the electromagnetic wave shielding material is applied such that the electromagnetic wave shielding material has the same height as the board pedestal or is lower than the board pedestal in the vicinity of the board pedestal.

16. The method for manufacturing an electronic control device according to claim 14, wherein, in the application step, the electromagnetic wave shielding material is applied so as to form a recess on a surface of the electromagnetic wave shielding material applied to be higher than the board pedestal.

17. The method for manufacturing an electronic control device according to claim 14, wherein, in the application step, the electromagnetic wave shielding material is applied to a position except in the vicinity of the board pedestal.

18. The method for manufacturing an electronic control device according to claim 14, wherein, in the application step, the electromagnetic wave shielding material is applied with a first application width in the vicinity of the board pedestal, and the electromagnetic wave shielding material is applied with a second application width narrower than the first application width in a portion other than the vicinity of the board pedestal.

19. The method for manufacturing an electronic control device according to claim 14, wherein
the installation pedestals of the housing includes first installation pedestals far from the board pedestals and second installation pedestals closer to the board pedestals than the first installation pedestals, and
in the application step, the electromagnetic wave shielding material is applied such that an application width of the electromagnetic wave shielding material at a boundary portion between the first installation pedestal and the second installation pedestal is wider than an application width of the electromagnetic wave shielding material at a portion other than the boundary portion.
